(19) United States
(12) Patent Application Publication
(10) Pub. No.: US 2026/0229448 A1
(43) Pub. Date: Aug. 6, 2026

(54) GRIDS FOR ELECTRON MICROSCOPY AND METHODS OF MANUFACTURING

(71) Applicant: Puxano BV, Diksmuide (BE)

(72) Inventors: Wouter VAN PUTTE, Diksmuide (BE); Marie-Aline MATTELIN, Diksmuide (BE); Benjamin HUET, Schaerbeek (BE)

(73) Assignee: Puxano BV, Diksmuide (BE)

(21) Appl. No.: 19/152,631

(22) PCT Filed: Feb. 9, 2024
(86) PCT No.: PCT/EP2024/053329

§ 371 Date: Jul. 31, 2025

(30) Foreign Application Priority Data
Feb. 10, 2023 (EP) 23156067.3

(51) Int. Cl. H01J 37/20; G03F 7/00

(52) U.S. Cl. CPC H01J 37/20; G03F 7/0017

(57) ABSTRACT

A grid (10) for use in electron microscopy to analyze samples (S), wherein said grid extends along a plane Po and comprises a mesh region (100) for receiving the samples and an edge region (200) surrounding said mesh region; wherein the mesh region is provided with one or more dome shaped relief regions (110) configured for holding the samples, said dome shaped relief regions extending out of the plane and being located at a distance from the edge region of the grid.

The present invention relates to grids for holding samples to be analyzed via electron microscopy or EM-microscopy, in particular grids to hold samples such as biomolecules to be analyzed via cryo-electron microscopy and methods for the manufacturing thereof.

An example to analyze samples is to perform an analysis via electron microscopy, such as cryo-electron microscopy. This technique provides structural analysis and/or determination of (macro) molecular sample structures, such as biomolecules. An example of a biomolecule is a protein.

Cryo-electron microscopy typically includes embedding samples in a thin layer of vitreous ice and the use of an electron beam to create (2D) projection images. The projected images can then be used to reconstruct a (3D) structure of the sample. The samples can be embedded having a uniform orientation or a random orientation. To obtain a good result for the structural analysis, random orientation is preferred. However, a high degree of random orientation is not always possible since some type of samples tend to orient themselves in a uniform manner. The uniform orientation of a sample in one direction is often referred to as a preferred particle orientation.

To address this orientation issue, several approaches have been tried out, for example the use of detergents or the addition of other “orientation-changing” biomolecules. However, these approaches require more steps and/or may not give certainty of a positive outcome such as a high-quality final analysis of the structure. Another approach is to actively tilt the grid holding the samples, for example approximately −60° to +60° so that the electron beam can pass through from different angles. The tilting is typically done between electron beam transmissions and results in a series of 2D images that can be combined to reconstruct a 3D image, a so-called “tomogram”. However, the tilting of the grid is rather burdensome and makes the apparatus or system used for the analyzing more complex. Another strategy that has been proposed is the use of affinity grids, whereby an analyte is immobilized in at least two different manners to the grid surface by introducing two analyte-immobilization strategies in a single analyte.

Hence, one object herein is to provide a technique to allow high quality analysis of samples with a high degree of positive outcome with reduced use and/or without having to rely on complex analyzing steps or systems.

### SUMMARY OF THE INVENTION

Thereto, a first aspect provides a grid for use in electron microscopy to analyze samples. The grid extends along a plane Po and comprises a mesh region for receiving the samples and an edge region surrounding said mesh region. The mesh region is provided with one or more dome shaped relief regions which are configured for holding the samples. The dome shaped relief regions extend out of the plane Po and are located at a distance from the edge region.

In particular, the one or more dome shaped relief regions extend out of the plane Po of the grid so as to form elevated surfaces. More in particular, the one or more dome shaped relief regions protrude out of the plane Po such that raised or elevated surfaces are formed.

The dome shaped relief regions allow a high-quality analysis of samples and provide a high degree of positive outcome. Furthermore, the analysis can be performed with reduced use or without having to rely on complex analyzing steps or systems.

The invention is based on the understanding that dome shaped relief regions of the mesh region hold the samples under various angles relative to the electron beam (EM-beam). This way, more angular sample data can be gathered via the projected images which result in a higher quality of the 3D reconstrued structure of the samples. This way, a detailed 3D structural reconstruction of the sample can be obtained.

In an embodiment, the edge region is flat and preferably extends along plane Po, or along a plane parallel thereto and/or the edge region is provided with one or more coordinated notches to be received by a corresponding clip ring. Having the edge flat allows proper connection to a clip ring, which ring can be used to hold the grid in place during analysis. The one or more coordinated notches allow an improved connection of the clip ring to edge region. This way, grid movement is minimized or avoided, and image quality can be improved.

In an embodiment, the one or more dome shaped relief regions are discrete regions, in particular discrete regions protruding out of the plane thereby forming elevated surfaces. This way, the dome shapes form individual distinct regions wherein the samples can be received. More so, such grid design can facilitate organization and analysis of the samples. The dome shaped relief regions are typically provided in a pre-coordinated manner. The mesh region may further comprise one or more flat regions. Said flat regions preferably surround the one or more relief regions.

The dome shapes can have any form, as long as the mesh region can hold samples under different angles and orientation relative to the electron beam. Preferably, the one or more of the dome shaped relief regions have a base extending in the plane Po. Said base can have a circular, polygonal or elliptical shape, preferably a circular shape. A circular shape improves positive outcome during manufacturing (e.g. pressing) and is believed to improve overall durability of the grid. More preferably, the one or more of the dome shaped relief regions have a top located above the plane Po at a distance of the base in plane Po, said distance being different than 0 μm, preferably at least 0.005 μm (or 5 nm), such as at least 0.01 μm.

In an embodiment, the one or more relief regions have a height h. Said height h is at least 0.005 μm (or 5 nm), such as at least 0.01 μm. This way, gathering of angular sample data can be improved. The height h is preferably between 0.005 μm-5 μm, more preferably between 0.01 μm-4 μm, even more preferably 0.1 μm-3.5 μm, such as between 0.5 μm-2 μm. By having the height as such, one can ease the analysis, e.g. facilitate an autofocus process. The height refers to the measurement of how high the dome shape extends outwardly out of the plane. More in particular, the domes form elevated or raised surfaces out of the plane each having a top, the height is then measured between the base of the dome within the plane P0 and said top.

In an embodiment, the relief regions are configured to extend in an angled fashion relative to the plane Po of the grid frame, wherein the angled fashion includes one or more angles between 0.1 to 70°, preferably between 1 to 60°, more preferably 10 to 50°, even more preferably 15° to 48°, such as 30°, said angles being the sharpest angle measured between a tangent touching a surface of the relief regions and the plane Po. By having such angular design, one can perform a detailed structural analysis of the samples, even if the samples have oriented themselves in a uniform manner.

In an embodiment, the mesh region comprises a first relief region and second relief region; the first relief region having a first dome shape, the second relief region having a second dome shape. The functionality and variety in use of the grid is improved by having multiple domes present on the grid. Preferably, the first dome shape is different than the second dome shape to further increase variety in use and functionality of the grid.

In an embodiment, the mesh region is provided with a multitude of holes of uniform size. Alternatively, said multitude of holes comprises a first pattern of holes with a first size and a second pattern of holes with a second size, wherein the first size of the holes in the first pattern is larger than the second size of the holes in the second pattern. By having the first and second holes with different size, the functional range of the grid is improved since one grid can be used for different types of samples. The multitude of holes may further comprise third or more patterns with holes having different sizes. Alternatively, the holes may have a random size, such as for example is the case for lacey grids.

The grid can have a layered structure comprising a film layer and a grid frame layer. In an embodiment, the film layer is configured for holding the samples and has a pattern or array of through holes. The pattern of through holes may include a first pattern of first holes having a first size, such as a diameter d1, that is larger than the thickness (t_{f})of the film layer, preferably at least 15 times larger. This way, one can broaden holding and/or embedding capacity of the grid for multiple types of samples. The grid frame layer is further included in the layered structure for supporting the film layer. The thickness of the grid frame layer is typically larger than the film layer, for example the film layer can have a thickness between 20 to 100 nm, such as 55 nm and/or the grid frame layer can have a thickness between 10 to 100 μm, for example 15 to 100 μm, such as 15 μm or 80 μm. An optional graphene layer may further be present. The graphene layer (or graphene film) can be arranged on top of the film layer, i.e. the side of the film layer away from the grid frame layer.

In an embodiment, the pattern of through holes in the film layer includes the first pattern of first holes having a first size, such as a first diameter d1 that is larger than the thickness t_{f} of the film layer, preferably at least 15 times larger such as at least 15 times larger and at most 20 times larger. This way, larger types of samples can be embedded more easily e.g. in the vitreous ice. The pattern of through holes in the film layer may further include a second pattern with second holes having a second size, such as second diameter d2, said second size being smaller than the first diameter d1 of the holes of the first pattern. By combining the first and second pattern each with different sizes of holes (relative larger and smaller), one can broaden the functional use range of the grid. More so, the grid can be deployed for a broader range of samples, e.g. samples having different types of sizes. It is understandable that such patterns and the benefits can be provided independently from the dome shaped relief regions.

A further aspect relates to a method for manufacturing a grid for electron microscopy such as cryo-electron microscopy. Herein, a substantially planar grid is transformed into a non-planar grid. The method comprising the steps of:
providing a planar grid, said grid or grid frame having a mesh region surrounded by an edge region;
pressing of the mesh region against a relief or a mold to form one or more dome shaped relief regions within the mesh region at a distance of the edge region.

By having the method (adapted) for the manufacture of the grid as described earlier, one can achieve the grids having the benefits as mentioned herein. Namely, the dome shaped relief regions allow a high-quality analysis of samples and provide a high degree of positive outcome.

A relief or a mold can be used to form the one or more dome reliefs. The relief used in the method is preferably obtained by:
applying a developable substance on a surface of a substrate, preferably a glass or silicon substrate, and forming a film thereon;
exposing and developing the film so as to create a relief structure on the substrate and preferably reflowing the created relief structure on the substrate.

The mesh region of the grid can be pressed against a relief so that the mesh region is provided with a corresponding relief structure. The relief is preferably made via photolithography. By deploying a spin coating technique, one can obtain dome shapes in accurate manner, and even with very fine and small geometries such as micro scale or even up to nanoscale.

The developable substance is preferably a positive resist to allow an optional reflow step.

The film is preferably applied on the substrate via spin coating. This way, a thin developable film can be achieved on the substrate.

Exposing of the applied film on the substrate may comprise subjecting the film to (UV-or light) radiation to selectively cure or crosslink parts of the film.

The positive resist may then be heated to allow reflowing. By having a reflowing step, smooth curvatures can be obtained and transferred to the grid, the smooth curvatures can benefit sample analysis.

The substrate and the relief structure on the substrate may further be subjected to an etching step, preferably inductively coupled plasma reactive ion etching, such that the substrate is provided with a corresponding relief structure.

This way, the pattern or structure of the film on the substrate can be transferred to the substrate itself. The substrate (itself) being provided with a relief structure can then be used to form desired dome shaped relief regions within the mesh region of the grid.

Additionally, or alternatively, a mold can be used to develop the relief regions in the mesh region. The mold is preferably obtained by anisotropic etching. By making the mold via anisotropic etching, one can create grooves, trenches or notches in an accurate manner on a surface on which the mesh region can be pressed such that the relief regions are created.

If a mold is used to form one or more dome shaped relief regions, said mold can be obtained by modifying a substrate S to create inclined surfaces thereon, wherein said inclined surfaces are made by aid of anisotropic etching. This way, grooves, trenches or cavities can be provided with fine geometries allowing fine relief regions.

In an embodiment, the method provides manufacturing a grid having a layered structure comprising a film layer for receiving and holding the samples, and a grid frame layer to support the film layer. A graphene layer can be present on top of the film layer or in between the film layer and the grid frame layer. The method may comprise:
pressing both layers (film layer and grid frame layer) together against the relief or mold so as to form the dome shaped relief regions, preferably at a distance of the edge region of the grids, or
applying the film layer after the grid frame layer has been pressed against the mold to form the dome shaped relief regions. By doing so, one can obtain grids having fine and well-shaped relief regions allowing for an improved structural analysis of samples.

A further aspect relates to a relief for use in the method for manufacturing the grid as described herein. The relief being obtained by:
applying a developable substance (such as a positive resist) on a surface of a substrate (preferably a glass substrate) and forming a developable film thereon;
developing the film so as to create a relief structure;
optionally, performing an etching step, preferably an inductively coupled plasma reactive ion etching step such that the substrate is provided with a corresponding relief structure. This way, a desired relief shape with fine geometries can be created on the surface substrate which then forms the relief. The substrate is preferably made of glass or silicon. The relief having the desired relief shape can then be used to create the (dome shape) relief regions in the mesh region of the grid. The developable substance can for example be a polymeric developable substance that can be exposed and developed e.g. by the (selective) application of or exposure to heat or light (selectively via mask or targeted laser) and subsequently be further developed, e.g. by use of developing substances/compositions/aids that can remove parts of the film on the substrate. In a preferred embodiment, the developable substance is a UV-sensitive polymeric developable substance.

Preferably, the developable substance is a negative or positive photoresist, preferably a positive photoresist. This way the portion of the photoresist that is exposed to light (e.g. via laser direct writing) becomes soluble to a photoresist developing substance/composition. The unexposed portion of the photoresist remains insoluble to the photoresist developing substance/composition and can stay on the substrate.

Preferably, the developable substance is applied via spin coating and/or wherein the exposing of the film comprises performing laser direct writing. This way finer and more accurate shapes can be created, even up to very small scales. By having such fine shapes, one achieves a desired relief which can be used for creating the dome shapes as mentioned earlier in a highly accurate manner.

In an embodiment, the relief structures on the substrate are subjected to a reflowing step. This way, smooth curvatures can be obtained which allow (when the relief is pressed against the grid) for the formation of smooth dome shapes in the mesh region of the grid. By having dome shapes with smooth curvatures, a good image quality and structural analysis of the samples can be obtained. The relief structures can for example be reflowed at elevated temperatures, e.g. around 100-120° C. or more.

A further aspect relates to a mold for use in the method according to any one of the above claimed methods, said mold being obtained by: modifying a substrate to create inclined surfaces thereon, wherein the modifying includes the formation of grooves, trenches, or cavities comprising the inclined surfaces.

Preferably the substrate is a silicon substrate (Si) as it allows fine anisotropic etching. The inclined surfaces are preferably made by aid of anisotropic etching. This way, fine geometries can be achieved which allow for an accurate and fine formation of dome shaped relief regions in the mesh region of the grid. Preferably, the cavities in the substrate are formed as a negative of the dome shaped relief regions as described earlier herein.

A further aspect relates to a grid for use in electron microscopy to analyze samples, wherein said grid comprises a mesh region for receiving the samples, wherein the mesh region is provided with a first pattern of holes with a first size and has a second pattern of holes with a second size, wherein the first size of the holes in the first pattern is larger than the second size of the holes in the second pattern. By having the first and second holes with different size, the functional range of the grid is improved since one grid can be used for different types of samples.

### BRIEF DESCRIPTION OF DRAWINGS

The invention will now be described in more details with respect to the drawings illustrating some embodiments of the invention. These are however not construed as being limiting.

FIG. 1A shows a perspective view of a grid according to an exemplary embodiment.

FIG. 1B shows a sideview of the grid shown in FIG. 1A.

FIG. 2 shows a principle wherein the grid of FIG. 1A is used in an electron microscopy process.

FIG. 3 and FIG. 4 show a cross sectional views of the grid of FIG. 2, at positions III and IV respectively.

FIG. 5 shows a top view of a grid according to an exemplary embodiment.

FIGS. 6A and 6B shows a part of a grid according to an exemplary embodiment with more detail.

FIG. 7 shows a perspective view of a grid according to an exemplary embodiment.

FIG. 8 shows the cross section through section line X-X in FIG. 7.

FIG. 9 shows exemplary embodiment(s) of a method for manufacturing a grid.

FIG. 10 shows an exemplary embodiment(s) of a method for manufacturing a grid.

FIG. 11 shows a perspective view of a grid framework (without thin film) having relief regions.

FIG. 12 shows a perspective view of a grid framework (with thin film) having relief regions.

### DETAILED DESCRIPTION

The grid as described herein can be used within several electron microscopy techniques or EM-techniques, these include among others the following techniques: cryo-EM wherein particles are embedded in a thin layer of ice, negative-stain EM wherein particles are embedded in a layer of heavy metal salts to increase the weak contrast of biological materials, micro-Ed wherein 3D crystals are hit with a focused electron beam. By using the grids as described herein one can record diffraction patterns from different sample angles, with minimal to no tilting steps of the grid. This way, a high-quality analysis of samples can be achieved with a high degree of positive outcome and with reduced use and/or without having to rely on complex analyzing steps or systems.

By having the grids with the provided reliefs in the mesh region, several types of samples can be analyzed in an improved way, including the samples which tend to orient themselves in a uniform manner. By using the grids as described herein one can reduce or omit complex analyzing steps or systems (such as grid tilting). Exemplary types of samples are biomolecules, proteins, viruses, proteoliposomes, vesicles etc. The samples can even be analyzed at near-atomic resolution e.g. by cryogenic electron microscopy or cryo-EM (used interchangeably).

In the figures, corresponding elements with the same or similar properties and benefits are indicated by the same reference numerals.

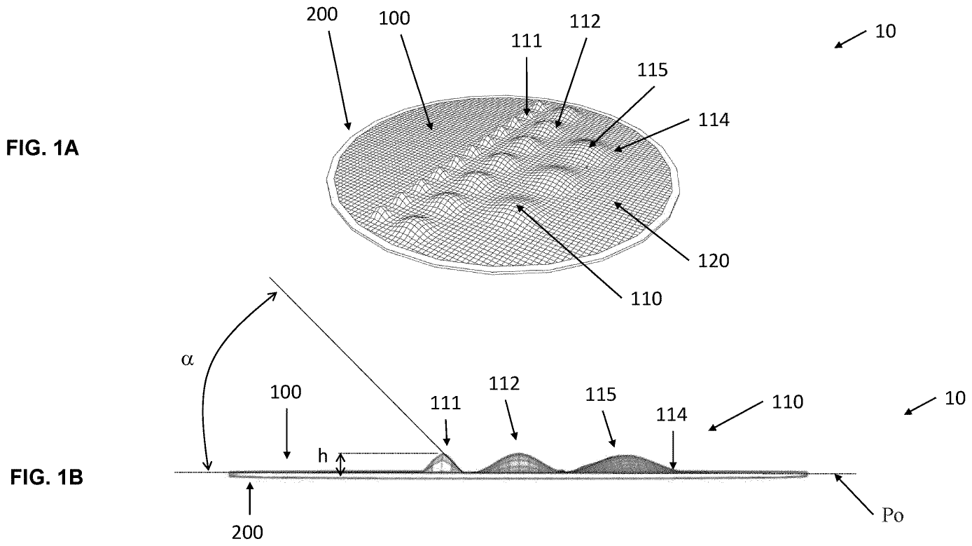

FIGS. 1A and 1B shows a grid 10 which has a mesh region 100 for receiving the samples and an edge region 200 surrounding the mesh region. The mesh region is provided with dome shaped relief regions 110. The figures further show in particular the dome shapes relief regions 110 form elevated surfaces. The dome shapes are positioned at a distance from the edge of the grid 10. The dome shaped relief regions within the mesh region are configured for holding the samples. Understandably, the mesh region has holes or cells through which the electron beam can pass. The type of mesh (e.g. the size of the holes therein) can be adapted according to the type of samples. The samples can be held on the mesh region. In this case the samples can be arranged either in the valleys of the dome shapes or can be arranged on top or on the side or both. Alternatively, or in addition thereto, the samples may also be embedded within the holes of the mesh region, e.g. within a liquid medium or within vitreous ice.

FIGS. 1A and 1B shows that grid 10 extends along a plane Po and the dome shapes 110 extend out of said plane and being located at a distance from the edge region 200 of the grid. More in particular, the figures show that the domes protrude from the plane Po, with other words, the domes form raised surfaces on the grid. The edge region 200 can be flat extending along plane Po as shown. Alternatively, the edge region may extend along a plane parallel thereto (not shown). In the latter case, can the mesh region be arranged in the middle of the grid while at least partially extending along plane Po and while the edge region extends along an inclined plane such as a plane parallel to plane Po. This way, the grid can for example have a U-shape.

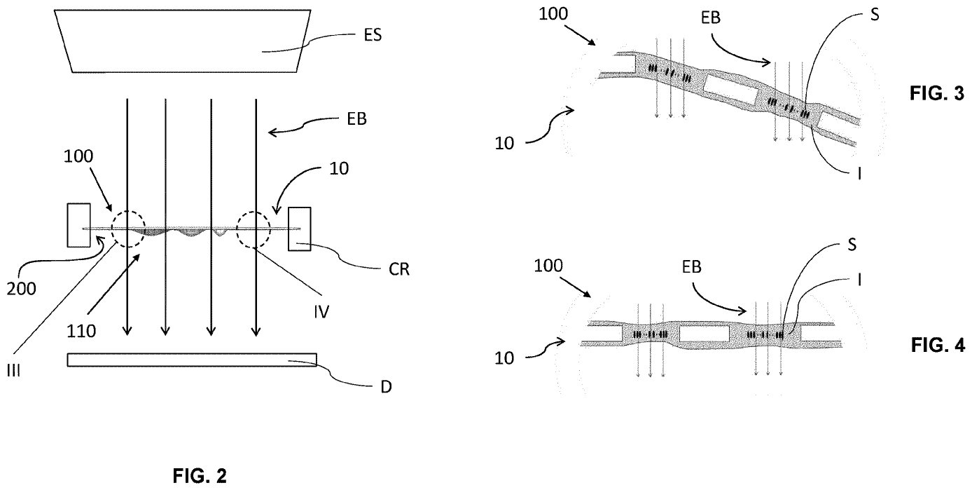

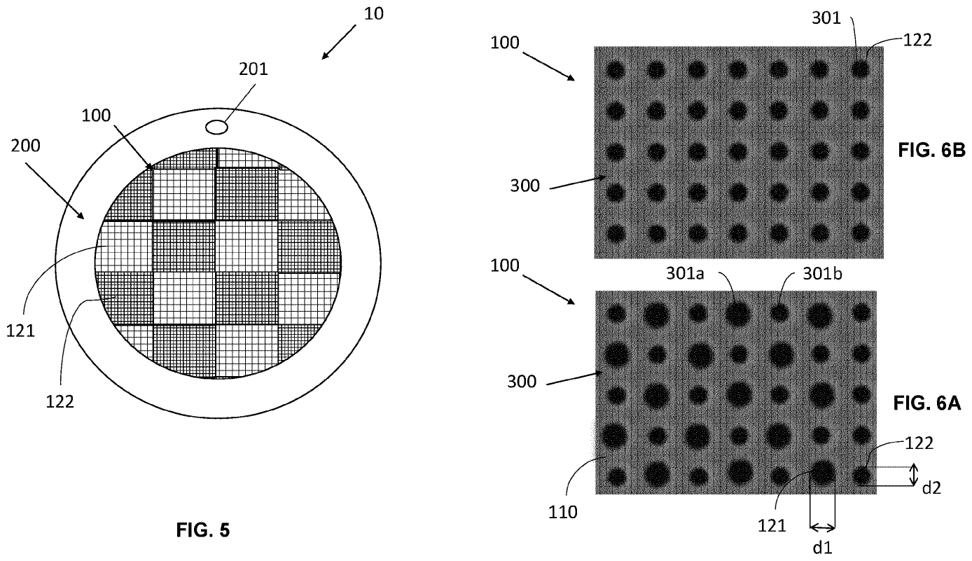

The edge region can be provided with a coordinated notch 201 (as illustrated in FIG. 5) to allow fixed connection to a clip ring CR (as illustrated in FIG. 2). The dome shapes 110 as shown are discrete and can be distinguished from each other. The dome shapes can be separated by a flat area 120 or the dome shapes can be directly adjacent to each other. The mesh region may further have flat regions 120 which can make up the rest of the mesh region. The flat region 120 can surround the dome shape(s) 120.

The shape of the dome shape relief regions in the mesh region is not limited and may have any form, as long as the mesh region can hold samples under different angles and orientation relative to the electron beam EB (see for example FIGS. 2, 3 and 4). Even if the samples S are grouped together in a uniform manner within the vitreous ice (in case of cryo-EM), the dome shapes can provide for a detailed structural analysis. Examples of preferred dome shapes are segmental, catenary, faceted, hemispherical, substantially hemispherical, trapezium, geodesic. Substantially hemispherical may for example be in the shape of a plano-convex lens.

The dome shaped relief regions 110 can have a base 114 extending in the plane Po. The base can have a circular, polygonal or elliptical shape, preferably a circular shape. A circular shape improves positive outcome during manufacturing (e.g. pressing) and is believed to improve overall durability of the grid. As said, the area 115 extending from the base 114 out of the plane can have any suitable shape. The base of a dome shape of the one or more dome shaped regions 110 preferably has a width and/or length which is at most 80% of the width and/or length of the grid, more preferably at most 75%, even more preferably at most 70% and most preferably at most 50% such as at most 40% or at most 30%. The base of the dome shape(s) can for example be substantially circular and have a diameter with a size that is at most 80% of the diameter of the grid. FIG. 1 further shows that the mesh region 100 of the grid 10 has a first dome shaped relief region 111 and a second dome shaped relief region 112 which have different dome shapes. By designing the mesh region as such, more sample data can be gathered. The first dome shape relief region 111 has a steeper incline relative to the plane Po as compared with the second relief region 112 (as can also be seen in FIG. 1B). More types of differently shaped relief regions 110 shapes may be present, e.g. a third relief region.

FIG. 1B further shows that the dome shapes can have height h, which is preferably at least 0.005 μm, such as between 0.01 μm-5 μm. As shown in the figure, the height of the dome is measured between the base of the dome in the plane Po and the top of said dome. Generally, and as shown in the figures, the dome shaped relief region(s) extends out of the plane Po forming elevated surfaces. With other words, the dome shaped relief region(s) form a raised part of the surface of the grid which extends out of the plane Po.

It is understandable that the height for each dome shape can be set independently and can be different from dome shape to dome shape. The heights of the dome shapes can also be substantially the same (as shown). The shape and dimensions of the dome shaped relief regions can be adapted accordingly to the type of sample. Larger samples may require larger dome shapes for example. In such cases, the change in relief height of two adjacent measuring positions on the dome, e.g. on dome area 115, located nearby to each other and substantially adjacently to each other is typically controlled such that an autofocus process of the imaging microscope is not tainted. With other words, in some cases, the dome shape(s) are better not too steep in view of an autofocus process that can be used during analysis.

FIG. 1B further illustrates that the relief regions 110 can extend in an angled fashion relative to the plane Po as for example indicated with symbol α which represents the sharpest angle measured between the tangent touching the surface of dome shape 111 and the plane. Preferably, the angle is at most 70°, preferably at most 55°, more preferably at most 50°, such as most 45°. This way, decent autofocus during sample analysis can be ensured. The angles can be between 0.1 to 70°, preferably between 1 to 60°, such as 1 to 55°, preferably 10 to 50°, more preferably 20° to 35°, such as 30°. Such angular design allows detailed structural analysis of the samples. As said above, a first dome shaped relief region 111 and a second dome shaped relief region 112 having different shapes are preferably present such that the samples are held or embedded under a different angle with respect to an electron beam EB. This way, more sample data can be gathered which allows for a higher structural sample analysis.

FIG. 2 shows a principle wherein a grid 10 is used in a process of electron microscopy, more in particular cryo-electron microscopy. The edge region 200 of the grid is fixed in clip ring CR. The clip ring CR can be used to hold the grid 10 in place during analysis. A coordinated notch 201 (see FIG. 5) allows for a fixed connection of the clip ring to edge region 200. This way, grid movement is minimized or avoided, and image quality can be improved. The mesh region 100 holds samples S in ice I. The electron beam source ES provides electron beam EB and projection images are captured via detector D. The samples may tend to orient themselves in a uniform orientation. However, a high degree of random orientation is desired so as to achieve a more detailed structural analysis. The dome shaped relief region(s) 110 allow for a high-quality structural analysis since more sample data can be gathered on the detector D as the electron beam EB can interact with the samples from different angles (as for example shown in FIG. 3). This is beneficial over the case where the samples S are only impacted from substantially the same angle (as for example shown in FIG. 4). To acquire more sample data, multiple dome shapes are preferably present in the mesh region 100, preferably at least two, more preferably at least three. The dome shapes are preferably distinguished from each other and preferably have different angles relative to the plane of the grid. In an embodiment, the mesh region comprises a first dome shape having a first incline and a second dome shape with a second incline. This way, more image information can be gathered from the sample under different angles.

FIG. 3 shows a part of the mesh region 100 (corresponding to position III in FIG. 2) where the samples S are embedded in ice I, e.g. within the holes of the film layer. Due to the inclined surface of the relief regions 110, the samples can be imaged with the electron beam EB under different angles, this way sample data can be gathered from different orientations without or with minimal tilting of the grid.

FIG. 4 shows an example of a flat area of the mesh region 100 (corresponding to position IV in FIG. 2) where the samples S are embedded in the ice I and have a uniform distribution. This way, the electron beam EB only gathers image data as seen from one orientation of the samples.

FIG. 5 shows an exemplary embodiment of a grid 10 as seen from a top view. The grid has a mesh region 100 for receiving samples and an edge region 200 surrounding the mesh region. The mesh region of said grid 10 has a first pattern 121 of holes with a first size (such as first diameter d1) and has a second pattern 122 of holes with a second size (such as second diameter d2). The holes can have any shape, such as circular or hexagonal.

The size of the holes in the first pattern 121 is larger than the size of the holes in the second pattern 122. The patterns may respectively cover areas positioned adjacently to each other (as seen in FIG. 5) or the first and second patterns may be arranged such that the (smaller) holes of the first pattern 122 are positioned in an alternating order with the (larger) holes of the second pattern (as seen in FIG. 6A).

In other embodiments, the holes can have substantially the same size (as seen in FIG. 6B). The holes can have different shapes, e.g. hexagonal, circular or the like. The size of the holes can be understood as the surface area in case of polygonal shapes or as a diameter in case of circular holes. By having holes with different sizes, one can improve the functional range of the grid since one grid can be used for different types of samples. This way, one can avoid having to change the grid when dealing with a different sample. Preferably, the holes of the first and second pattern are adjacently positioned in an alternating order (as best seen in FIG. 6A). Preferably, the pitch distance from center to center of the holes in two adjacent rows is substantially equal as seen over the total area of the mesh region. This way, grid manufacturing and data acquisition can be facilitated. The mesh region can also be provided with a third or even more patterns of holes, each with different sizes and/or locations on the grid. Thereby, one can even further improve the functional range of the grid. It is understandable that the patterns of the holes with different sizes in the mesh region 100 can be incorporated and that the benefits thereof can be achieved independently from the dome shaped relief regions 110 within the mesh region of the grid, though these can be combined.

FIG. 6A shows an example where holes (larger holes 121 and smaller holes 122) are positioned in an alternating order. First holes 121 are provided in a first pattern and second holes 122 are provided in a second pattern. The first holes have a larger diameter d1 than the diameter d2 of the second holes 122, preferably d1 is at least 2% larger that d2, preferably 5% larger, even more preferably at least 10% so as to provide for a broader functional or sample type range of the grid. The grid can be provided with holes with different diameters for example chosen from a combination of diameters around 800, 600, 400 or 200 nm. Preferably, the grid has a first pattern 121 of which the holes are 800 nm or more and a second pattern 122 of which the holes are smaller than 800 nm. This way, the grid can be used for multiple sample types having different kinds of molecular structures, sizes, shapes, weights, etc.

FIG. 6B shows an example of where holes in the mesh region 100 have substantially the same size, a pattern of holes is shown having holes 122 of the same size.

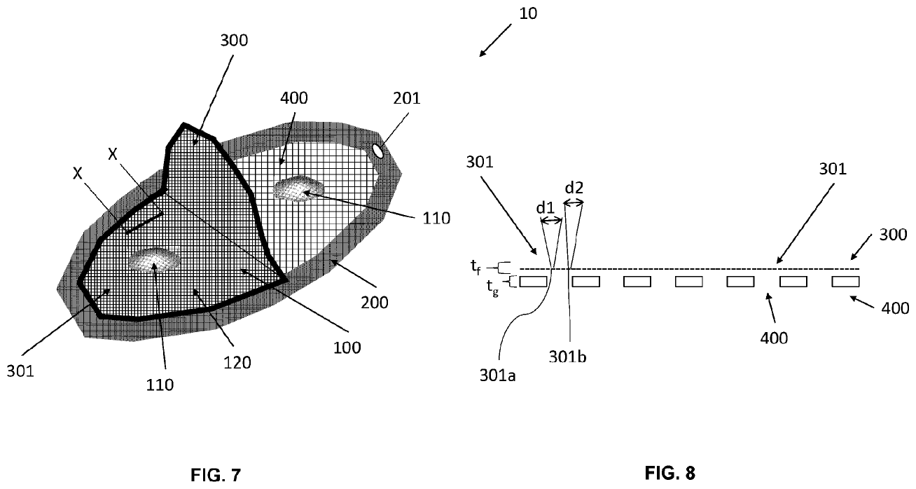

FIG. 7 shows a view of a grid 10 having a layered structure with a film layer 300 and a grid frame layer 400. The grid comprises mesh region 100 and edge region 200. The edge region 200 can have a coordinated notch 201. The mesh region can be provided with one or more dome shaped relief regions 110 at a distance from the edge.

The grid 10 having a layered structure comprises a film layer 300 configured for holding samples. The grid 10 further has a grid frame layer 400 for supporting the film layer. This way, dimensional stability can be achieved since the film layer is typically thin and mechanically sensitive or unstable. The film layer 300 has a pattern of through holes 301. The holes of the film layer are typically smaller than the holes of the grid frame layer 400. The through holes can be configured for embedding the samples, e.g. embedding the samples in ice I. The pattern of through holes 301 can comprise patterns with holes of any suitable shape, e.g. circular or polygonal. Exemplary shapes are triangle, quadrilateral, pentagon, hexagon etc. Preferably the through holes 301 in the film layer 300 have a hexagonal shape (such as a honeycomb). The pattern of through holes 301 in the film layer 300 may include a first pattern 121 of first holes having a first size, such as a diameter d1, that is larger than the thickness tf of the film layer 300, preferably at least 15 times larger. This way, one can achieve a broad holding and/or embedding capacity of the grid for multiple types of samples. The film layer 300 may further have a second pattern 122 with second through holes that are smaller than the through holes of the first pattern 121 in the film layer 300, this way the embedding of smaller sample types can be improved, e.g. embedding of the samples in ice. The first and second patterns in the film layer 300 can be arranged as explained earlier in connection to FIGS. 5 and 6A and 6B.

FIG. 8 illustrates layers as seen through section line X-X of FIG. 7. The film layer 300 is supported by the grid frame layer 400 also referred to as the grid frame. The thickness of the grid frame layer is typically larger than the film layer, this way dimensional stability can be provided. The film layer 300 can have a thickness t_{f} between 20 to 75 nm, such as 55 nm. The grid frame layer 400 can have any thickness t_{g} between 10 to 100 μm, for example 60 to 100 μm, such as 15 or 80 μm.

Optionally, a graphene layer (not shown) may be present on the film layer 300 (the side facing away from the grid layer) or between the film layer 300 and the grid frame layer 400. The film layer 300 comprises holes 301a having a first shape indicated by ds 1 and holes 301b having a second shape indicated by d2. This way, the range of embedding different kinds of samples can be broadened.

The film layer 300 can be made of pure or alloyed materials, examples are Silicon Nitride (SiₓN_{y}, wherein x and y are suitably chosen), Pure Silicon, Silicon Dioxide, or a metal, preferably silver (Ag) or gold (Au), or a combination of materials, such as an alloy with gold (Au), palladium (Pd), platina (Pt), such as Au/Pd for example Au/Pd (80%/20%), Au/Pt, Au/Ag.

Silicon Nitride (SiₓN_{y}) is good for higher temperatures, such as temperatures above 350° C., such as 1000° C. Silicon Nitride may further have insulating and/or hydrophobic characteristics.

Pure Silicon (S) grids can offer greater stability at high beam currents and at moderately high annealing temperatures (up to 600° C.), furthermore chromatic blur may be reduced.

Silicon Dioxide (SiO₂) provides for an improved handling of harsh deposition and chemical conditions by providing an ideal balance of imaging resolution and mechanical strength.

In a preferred embodiment, the film layer is (a thin film) made from one of Au/Pd, Au/Pt or SiO2. The grid frame layer 400 can be made with or from any of: copper (Cu) or gold (Au), preferably copper. The grid frame layer can also be made with or from: copper/palladium, copper/rhodium, molybdenum, rhodium, nickel (Ni).

A suitable layer configuration is a film layer 300 made with one of Au/Pd, Au/Pt and a grid frame layer 400 made with copper (Cu), preferably pure copper or nickel.

Another suitable layer configuration is a film layer 300 made with SiO2 and a grid frame layer 400 made from gold (Au), preferably pure gold. The grid frame layer 400 can have cells or holes of any shape, such as circular or hexagonal. The cells of the grid frame 400 are typically larger than the holes through film layer 300.

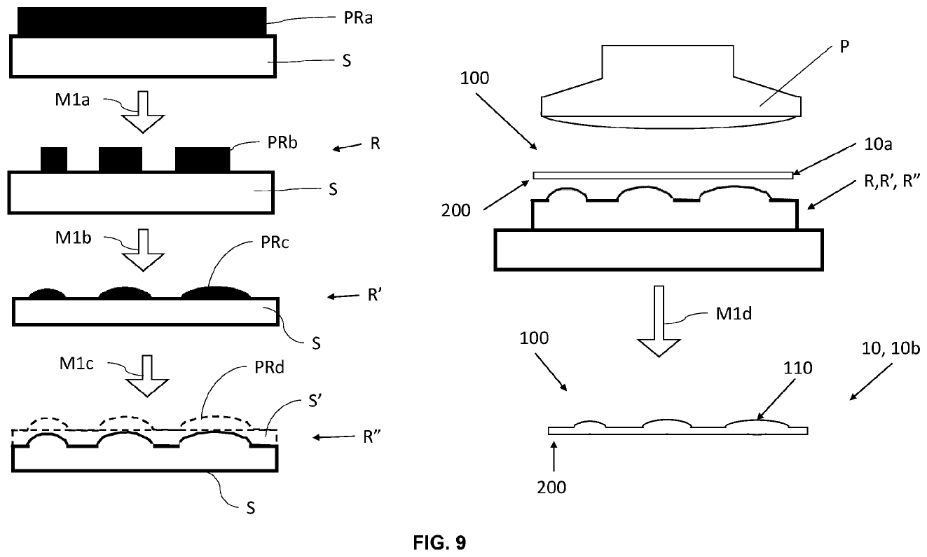

FIG. 9 shall now be used to explain how a relief (indicated with any of R, R′, R″) can be made and used in a method to transform a planar grid 10a into a non-planar grid 10b, more in particular a grid 10 with dome shaped relief regions 110 within the mesh region 100, preferably at a distance from the edge of the grid.

First, relief R is obtained by applying a developable substance PRa, such as a (polymeric) positive resist, on a surface of a substrate S. Preferably, substance PRa is applied via spin coating. This way, a fine film layer can be obtained on the substrate which allows the formation of relief regions with small geometries. The film layer of developable substance formed on the substrate may have a thickness between 0.2-15 μm.

Step M1a illustrates that after the film of substance PRa is applied on the substrate S, the film is exposed and developed so as to form relief structures PRb. This way the substrate S and the relief structures PRb formed thereon can be used as a relief R which allows the formation relief regions within the mesh region 100 of a grid 10. During step M1a, the substance can be exposed by for example (selective) application of heat or light (selectively via mask or targeted laser) and subsequently be further developed, e.g. by use of a developing substance/composition/aid that can remove parts of the film on the substrate and thereby leaving behind a relief structure PRb made of the developed substance on the substrate S. In preferred embodiments, the film of substance PRa is exposed with UV light to selectively cure or crosslink the developable substance forming the film. The developable substance PRa can be a negative or positive photoresist, preferably a positive photoresist. In the latter, the portion of the positive photoresist that is exposed to light (i.e. via laser direct writing) becomes soluble to a photoresist developing substance/composition. The unexposed portion of the photoresist remains insoluble to the photoresist developing substance/composition and can stay on the substrate. By performing laser direct writing, highly accurate and fine reliefs can be obtained which allow for improved relief shapes 110a on the grid 10.

Step M1b indicates a reflowing step. The reflowing may be performed at elevated temperatures of more than 60°, such as more than 100°. The elevated temperature may be provided by a heat source (not shown) such as a hot plate. By reflowing the material PRb on the substrate S, relief structures PRc with smoother curvatures can be obtained which can be used to create smoother dome shaped relief regions 110 which allow improved sample analysis. Such smooth dome shapes can be obtained by pressing the relief R′ on the mesh region 100 of a planar grid 10a to create a non-planar grid 10b.

Step M1c indicates an etching step so that any of the created relief structures PRb or relief structures PRc (if reflowed) can be transferred to the substrate S, preferably via inductively coupled plasma reactive ion etching. This way a part of the substrate S′ can be etched away so that a relief structure is formed out of substrate S. By doing so, a more durable relief R″ can be obtained. The substrate is preferably a glass substrate or a substantially pure silicon substrate.

The reliefs R, R′, R″ can then be used to create relief regions in a mesh region 100 of a non-planar grid as indicated by step M1d. As shown, a presser P is used to press the mesh region 100 of the planar grid 10a against the relief R, R′, R″. The presser (or press element) may be made from a material softer that the material of the grid. This way, one avoids or reduces undesired press damage on the grid. The presser P can be a flexible roll and/or the presser may have a shape that is opposite to the shape of the relief R.

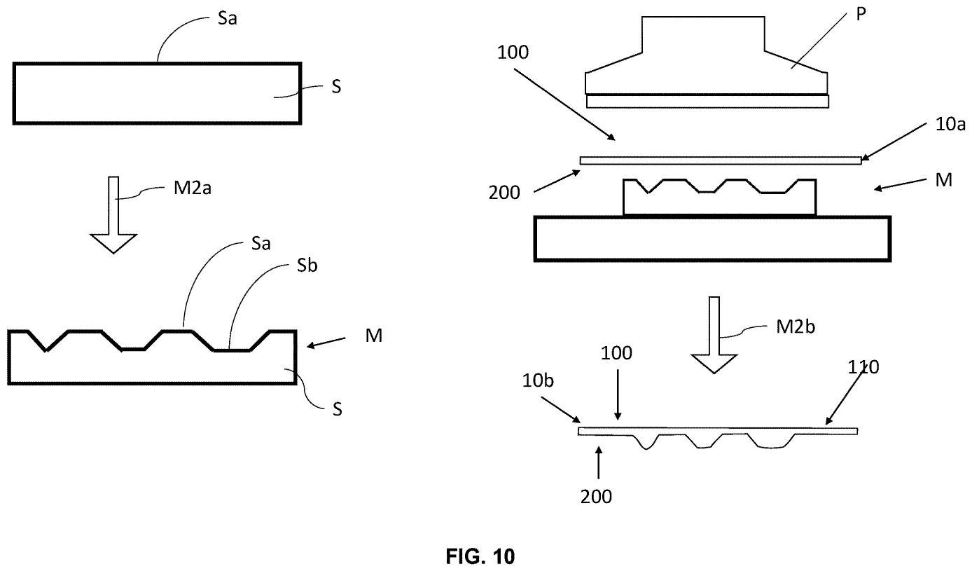

FIG. 10 shows a method wherein a mold M is used to create one or more relief regions 110 in the mesh region 100 of the non-planar grid 10b. The relief region 100 is positioned at a distance from the edge of the grid 10b. The mold M is obtained by modifying substrate S. The substrate is preferably a Silicon (Si) substrate. The surface Sa of substrate S is provided with inclined surfaces Sb, indicated with step M2a. Any suitable shape can be made in the surface of the substrate S, examples are as grooves, trenches, or cavities. The shape created comprises inclined surfaces which can be used to create the relief regions in the mesh region 100 of the planar grid 10a to create a non-planar grid 10b. The inclined surfaces Sb are preferably created by aid of anisotropic etching. This way, shapes Sb in the substrate S can be created as desired so as to create the mold. In a particular embodiment, the mold is a glass or silicon mold. The mold can have dome shaped cavities or dimples with dimensions smaller than 80 micrometer.

By pressing the planar grid 10a with the presser P against the mold M, the created shapes can be transferred so as to make a non-planar grid 10b with relief regions in the mesh region 100 thereof, as indicated with step M2b. In particular, the relief regions are positioned at a distance of the edge region 200 of the grid so that a good fixation to a clip ring CR can be ensured. The presser P may be formed as a roller (not shown). The presser P preferably has a soft surface that is configured not to damage the grid when pressed thereon. Alternatively, or in addition thereto, the presser P may comprise a relief shape which corresponds to the mold in a manner of “positive-negative”. With other words, the presser P and the mold M can be puzzled together with the grid 10 positioned in between.

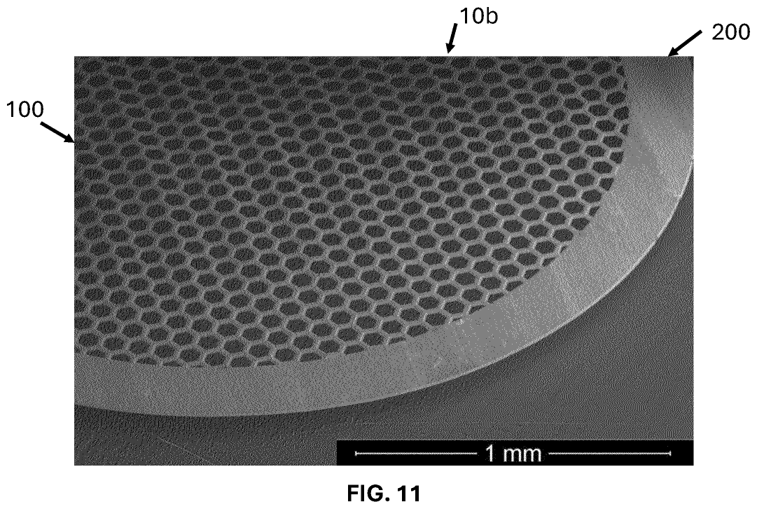

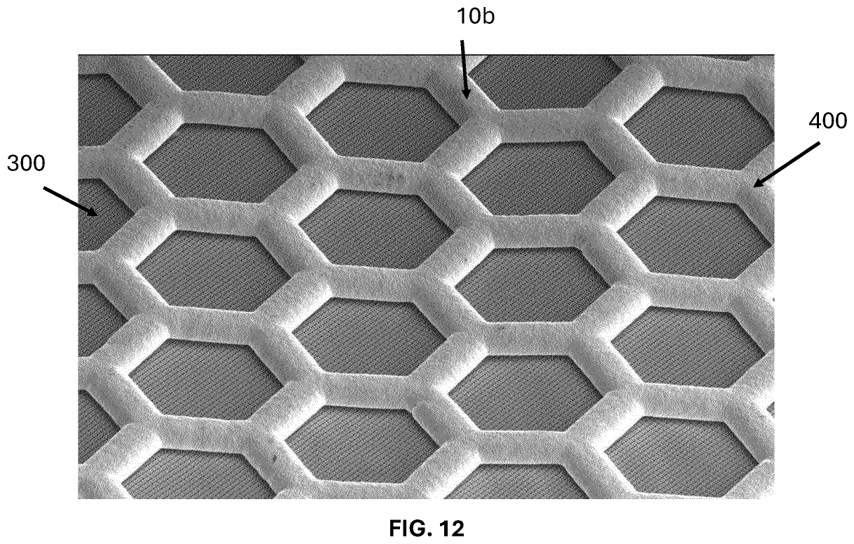

FIGS. 11 and 12 show a grid frame layer made in accordance with the method disclosed herein. This grid frame can be used in the formation of a thin film having relief regions, wherein the method for making such film comprises applying the film layer after the grid frame layer has been pressed against a mold to form the dome shaped relief regions. In FIG. 11 it is shown that the grid frame comprises relief regions. By pressing the planar grid 10a with a presser P against the mold M (see FIG. 10), the created shapes can be transferred so as to make a non-planar grid 10b with relief regions in the mesh region 100 thereof. In particular, the relief regions are positioned at a distance of the edge region 200 of the grid. After application of the film layer to the preformed grid frame, these relief regions will also be formed in the thin film layer. This is illustrated in FIG. 12, wherein the film layer 300 is positioned at the underside of the grid frame layer 400, and clearly follows the contours (i.e. shape) of the non-planar grid. By doing so, one can obtain grids having fine and well-shaped relief regions allowing for an improved structural analysis of samples.

The skilled person will appreciate based on the above description that the invention can be embodied in different ways and on the basis of different principles. The invention is not limited to the above-described embodiments. The above-described embodiments and the figures are purely illustrative and serve only to increase understanding of the invention. The invention will therefore not be limited to the embodiments described herein but is defined in the claims.

1. A grid for use in electron microscopy to analyze samples, wherein said grid extends along a plane Po and comprises
a mesh region for receiving the samples; and
an edge region surrounding said mesh region;
wherein the mesh region is provided with one or more dome shaped relief regions configured for holding the samples, said dome shaped relief regions extending out of the plane and being located at a distance from the edge region of the grid.

2. The grid according to claim 1, wherein the edge region is flat and extends along the plane Po or along a plane parallel thereto and/or wherein the edge region is provided with one or more coordinated notches to be received by a corresponding clip ring.

3. The grid according to claim 1, wherein the one or more dome shaped relief regions are discrete regions.

4. The grid according to claim 1, wherein the mesh region further comprises one or more flat regions, said flat regions surrounding the one or more relief regions.

5. The grid according to claim 1, wherein one or more of the dome shaped relief regions have a base extending in plane Po, wherein said base has a circular, polygonal or elliptical shape.

6. The grid according to claim 1, wherein one or more of the dome shaped relief regions have a segmental, catenary, faceted, arabic, hemispherical, trapezium, or geodesic dome outline.

7. The grid according to claim 1, wherein one or more relief regions have a height h, wherein height h is at least 0.005 μm.

8. The grid according to claim 7, wherein the height h is between 0.005 μm-5 μm.

9. The grid according to claim 8, wherein the height h is between 0.01 μm-4 μm.

10. The grid according to claim 1, wherein the relief regions are configured to extend in an angled fashion relative to the plane Po, wherein the angled fashion includes one or more angles between 0.1 to 70°, said angles being the sharpest angle measured between a tangent touching a surface of the relief regions and the plane Po.

11. The grid according to claim 10, wherein the one or more angles are between 1 to 60°.

12. The grid according to claim 11, wherein the one or more angles are between 10 to 50°.

13. The grid according to claim 1, wherein the mesh region comprises a first relief region and a second relief region; the first relief region having a first dome shape, the second relief region having a second dome shape, wherein the first dome shape is different than the second dome shape.

14. The grid according to claim 1, wherein the mesh region comprises:
a first pattern of holes with a first size and a second pattern of holes with a second size; wherein the first size of the holes in the first pattern is larger than the second size of the holes in the second pattern, and/or wherein the holes of the first and second pattern are adjacently positioned in an alternating order, and/or wherein the pitch distance from center to center of the holes in two adjacent rows is substantially equal as seen over the total area of the mesh region.

15. The grid according to claim 1, wherein the grid comprises a layered structure, said layered structure comprising:
a film layer with a pattern of through holes configured for holding the samples;
a grid frame layer for supporting the film layer;
wherein the pattern of through holes in the film layer includes:
a first pattern of first holes having a first size that is larger than a thickness t_{f} of the film layer and a second pattern with second holes having a second size which is smaller than the first size of the holes of the first pattern.

16. The grid according to claim 1, wherein the one or more dome shaped relief regions protrude out of the plane Po such that elevated surfaces are formed.

17. A method for manufacturing a grid for electron microscopy, the method comprising:
providing a planar grid, said grid having a mesh region surrounded by an edge region;
pressing of the mesh region against a relief or a mold so as to form a grid having one or more dome shaped relief regions within the mesh region at a distance of the edge region.

18. The method according to claim 17, wherein the relief is obtained by:
applying a positive resist on a surface of a substrate and forming a film thereon;
exposing and developing the film so as to create a relief structure on the substrate; and
reflowing the created relief structure on the substrate.

19. The method according to claim 18, further comprising:
etching the relief structure on the substrate via inductively coupled plasma reactive ion etching, such that the substrate is provided with a corresponding relief structure.

20. The method according to claim 17, wherein the mold is obtained by modifying the substrate to create inclined surfaces thereon, wherein said inclined surfaces are made by aid of anisotropic etching.
